(19) United States
(12) Patent Application Publication
(10) Pub. No.: US 2009/0159214 A1
(43) Pub. Date: Jun. 25, 2009

(54) MICROWAVE PLASMA SOURCE AND PLASMA PROCESSING APPARATUS

(75) Inventor: Shigeru KASAI, Nirasaki-shi (JP)

Correspondence Address: OBLON, SPIVAK, MCCLELLAND MAIER & NEUSTADT, P.C., 1940 DUKE STREET, ALEXANDRIA, VA, 22314, US

(73) Assignee: TOKYO ELECTRON LIMITED, Minato-ku (JP)

(21) Appl. No.: 12/361,040

(22) Filed: Jan. 28, 2009

Related U.S. Application Data
(63) Continuation of application No. PCT/JP07/64345, filed on Jul. 20, 2007.

(30) Foreign Application Priority Data
Jul. 28, 2006 (JP) 2006-206260
Jun. 27, 2007 (JP) 2007-168661

(51) Int. Cl. H01L 21/306; C23C 16/00; C23F 1/00; B01J 19/12

(52) U.S. Cl. 156/345.41; 118/723 AN; 422/186.04

(57) ABSTRACT

A microwave plasma source (2) is provided with a microwave outputting section (30) which outputs plural divided microwaves, and a plurality of antenna modules (41) for guiding the plural divided microwaves into a chamber. Each antenna module (41) is provided with an amplifier section (42) having one or more amplifier (47) for amplifying a microwave, and an antenna section (44) having an antenna (51) for radiating the amplified microwave into the chamber, and a tuner (43) for adjusting impedance in a microwave transmission path. The tuner (43) is integrally arranged with the antenna section (44) to be located close to the amplifier (47).

This application is a Continuation Application of PCT International Application No. PCT/JP2007/064345 filed on Jul. 20, 2007, which designated the United States.

### FIELD OF THE INVENTION

The present invention relates to a microwave plasma source and a plasma processing apparatus using the same.

### BACKGROUND OF THE INVENTION

In a manufacturing process of a semiconductor device or a liquid crystal display device, a plasma processing apparatus such as a plasma etching apparatus and a plasma CVD film forming apparatus has been employed to perform a plasma process, e.g., an etching process or a film forming process, on a substrate to be processed such as a semiconductor wafer, a glass substrate, and the like.

There are well-known plasma generating methods used in the plasma processing apparatus, e.g., a method including steps of supplying a processing gas into a chamber with parallel plate electrodes disposed therein; feeding specific powers to the parallel plate electrodes; and generating a plasma by capacitive coupling between the electrodes and a method including steps of accelerating electrons by an electric field produced by a microwave which is introduced into a chamber and a magnetic field generated by a magnetic field generating unit which is installed outside the chamber; colliding the accelerated electrons with neutral molecules of a processing gas; and generating a plasma by ionization of the neutral molecules, or the like.

In the latter method utilizing a magnetron effect due to the electric field produced by the microwave and the magnetic field generated by the magnetic field generating unit, a microwave of a predetermined specific power is supplied to an antenna disposed in the chamber through a waveguide/coaxial tube so that the microwave is emitted from the antenna into a processing space in the chamber.

A typical and conventional microwave introducing unit includes a microwave oscillator having a magnetron for outputting a microwave whose power is regulated to a predetermined specific value and a microwave generating power supply for supplying a DC anode current to the magnetron. The conventional microwave introducing unit is configured to radiate the microwave output from the microwave oscillator into a processing space in a chamber via an antenna.

However, the microwave introducing unit using the magnetron has a drawback in which the cost for the equipment and the maintenance thereof are high due to a short life span of about half a year of the magnetron. Further, the magnetron has oscillation stability of approximately 1% and output stability of approximately 3% so that each of deviation thereof is large. For that reason, it is difficult to have a stable microwave oscillation.

Therefore, Japanese Patent Laid-open Application No. 2004-128141 discloses therein a technique for ensuring a long life of the device and stable microwave output by generating required high power microwaves by amplifying low-power microwaves through the use of amplifiers using respective semiconductor amplifying devices, i.e., solid state amplifiers. This technique involves steps of dividing a microwave by a divider; amplifying the microwaves outputted from the divider by the solid state amplifiers; and combining the microwaves amplified by the solid state amplifiers by a combiner.

The technique described in Japanese Patent Laid-open Application No. 2004-128141 is disadvantageous in that an accurate impedance matching is required in a combiner; a large-sized isolator is required to transmit to the isolator the high power microwaves outputted from the combiner; and an output distribution of the microwave cannot be adjusted in the surface of the antenna. In order to mend such drawbacks, Japanese Patent Laid-open Application No. 2004-128385 suggests a technique for dividing microwaves by using a divider into a plurality of microwaves and amplifying the divided microwaves by amplifiers. Thereafter, microwaves are radiated from a plurality of antennas without combining the microwaves by a combiner, and instead, the microwaves are combined in a space.

However, this technique is disadvantageous in that the apparatus becomes complicated because two or more large-sized stub tuners are installed in each of the divided channels and because a mismatching portion needs to be tuned. Further, the impedance of the mismatching portion cannot be adjusted with high accuracy.

### SUMMARY OF THE INVENTION

The object of the present invention is to provide a microwave plasma source capable of adjusting impedance with high accuracy without requiring a scaled up and complicated configuration.

Another object of the present invention is to provide a plasma processing apparatus using the microwave plasma source.

In accordance with a first aspect of the present invention, there is provided a microwave plasma source for forming a microwave plasma in a chamber, including: a microwave outputting section for outputting a microwave; an amplifier section having one or more amplifiers for amplifying the microwave; an antenna section having an antenna for radiating the amplified microwave into the chamber; and a tuner for adjusting impedance in a microwave transmission path, wherein the tuner is integrally arranged with the antenna section to be located close to the amplifiers.

In the first aspect, preferably, the antenna has a planar shape, and is provided with a plurality of slots.

In accordance with a second aspect of the present invention, there is provided a microwave plasma source for forming a microwave plasma in a chamber, including: a microwave outputting section for outputting plural divided microwaves; and a plurality of antenna modules for guiding the divided microwaves into a chamber, wherein each antenna module includes: an amplifier section having one or more amplifiers for amplifying a microwave; an antenna section having an antenna for radiating the amplified microwave into the chamber; and a tuner for adjusting impedance in a microwave transmission path, wherein the tuner is integrally arranged with the antenna section to be located close to the amplifiers.

In the second aspect, preferably, the microwaves guided to the chamber via the antenna modules are combined in a space in the chamber. Further, the amplifier section may have a phase shifter for shifting a phase of a microwave. Moreover, the antenna may be formed in a planar shape, and may have a plurality of slots. In case that the plurality of slots are formed, the amplifier section may also have a phase shifter for shifting a phase of a microwave, and, in this case, the antenna modules are arranged such that slots of neighboring antenna modules are disposed to make 90° therebetween, and the phase shifter adjusts phase difference between neighboring antenna modules to be 90°. Thus, circular polarized waves can be obtained.

In the microwave plasma source of the first and the second aspect, if the antenna has a planar shape, and is provided with a plurality of slots, the slots may have an arc-shape. In this case, the antenna section may preferably have a ceiling plate formed of a dielectric through which the microwave radiated from the antenna is transmitted and a dielectric wave retardation member for shortening a wavelength of the microwave reaching the antenna, the wave retardation member being provided at an opposite side of the ceiling plate with respect to the antenna. By adjusting a thickness of the wave retardation member, a phase of the microwave may be adjusted. Further, the ceiling plate may have a rectangular shape and may be divided into two parts at a center portion thereof.

In the microwave plasma source of the first and the second aspect, preferably, the tuner and the antenna form a lumped constant circuit. Further, the tuner and the antenna may serve as a resonator. Moreover, the tuner may preferably be a slug tuner having two dielectric slugs.

It is preferable that the amplifiers have a semiconductor amplifying device. Further, the tuner and the antenna section may be integrally arranged in a common housing. The amplifiers may be connected in series to the antenna section via the tuner by a connector extending upward from the housing or may be installed directly on a top surface of the housing. The amplifier section may further have an isolator for separating a reflected microwave from the microwave outputted from the amplifiers to the antenna.

In the microwave plasma source of the first and the second aspect, the microwave plasma source further includes a feed power conversion unit for optimally supplying microwave power from the amplifiers to the tuner.

Preferably, the feed power conversion unit has a feed power excitation member for performing a non-contact power supply via a dielectric and an antenna, and, more preferably, the feed power excitation member has one or more open stub microstrip lines formed on a dielectric board; one or more connectors for supplying the microwave power from the amplifiers to the microstrip lines; a dielectric member which serves as a resonator and transmits the microwave power from the microstrip lines; and a slot antenna for radiating the microwave transmitted through the dielectric member to the tuner.

In this case, the numbers of the connectors and the microstrip lines may be greater than one, respectively, and each of the connectors may be connected to an amplifier such that the microwave power from the amplifiers may be combined in a space via the microstrip lines.

The feed power excitation member may have one or more patch antennas formed on a dielectric board; one or more connectors for supplying the microwave power from the amplifiers to the patch antennas, and a dielectric member for transmitting the microwave power radiated from the patch antennas therethrough to radiate the transmitted microwave power to the tuner. In this case, the numbers of the connectors and the patch antennas are greater than one, respectively, and each of the connectors may be connected to an amplifier such that the microwave power from the amplifiers may be combined in a space via the path antennas.

The feed power excitation member may further have a reflecting plate which is provided on an opposite surface of a microwave power radiating surface to reflect microwave power.

In accordance with a third aspect of the present invention, there is provided a plasma processing apparatus for performing plasma processing on a substrate to be processed in a chamber, the plasma processing apparatus including: the chamber accommodating the substrate to be processed; a gas supply mechanism for supplying gas into the chamber; and a microwave plasma source for turning the gas supplied into the chamber into a plasma by a microwave.

The microwave plasma source includes: a microwave outputting section for outputting a microwave; an amplifier section having one or more amplifiers for amplifying the microwave; an antenna section having an antenna for radiating the amplified microwave into the chamber; and a tuner for adjusting impedance in a microwave transmission path, wherein the tuner is integrally arranged with the antenna section to be located close to the amplifiers.

In accordance with a fourth aspect of the present invention, there is provided a plasma processing apparatus for performing plasma processing on a substrate to be processed in a chamber, the plasma processing apparatus including: the chamber accommodating the substrate to be processed; a gas supply mechanism for supplying gas into the chamber; and a microwave plasma source for turning the gas supplied into the chamber into a plasma by a microwave.

The microwave plasma source includes: a microwave outputting section for outputting plural divided microwaves; and a plurality of antenna modules for guiding the divided microwaves into the chamber.

Each antenna module includes: an amplifier section having one or more amplifier for amplifying a microwave; an antenna section having an antenna for radiating the amplified microwave into the chamber; and a tuner for adjusting impedance in a microwave transmission path, wherein the tuner is integrally arranged with the antenna section to be located close to the amplifiers.

In the microwave plasma source of the third and the fourth aspect, preferably, the gas supply mechanism has a first gas supply mechanism for introducing a plasma generating gas, and a second gas supply mechanism for introducing a processing gas, wherein the plasma generating gas from the first gas supply mechanism is turned into a plasma by the microwave, and the processing gas from the second gas supplying mechanism is turned into a plasma by the plasma.

In accordance with the present invention, in the microwave plasma source for forming a microwave plasma in the chamber, the tuner and the antenna section are integrally arranged and thus need to be scaled down, compared to the case where they are separately arranged. Also, the microwave plasma source can also be scaled down. Moreover, by providing the amplifiers, the tuner and the antenna to be located close to one another, an antenna installation portion where an impedance mismatching exists can be tuned with high accuracy by the tuner and, also, the effects of reflection can be reliably solved.

### BRIEF DESCRIPTION OF THE DRAWINGS

FIG. 1 is a cross sectional view showing a schematic configuration of a plasma processing apparatus having a microwave plasma source in accordance with an embodiment of the present invention.

FIG. 2 provides a block diagram for explaining a schematic configuration of the microwave plasma source in accordance with the embodiment of the present invention.

FIG. 3 describes an example of a circuit configuration of a main amplifier.

FIG. 4 presents a cross sectional view of a tuner and an antenna section in the apparatus of FIG. 1.

FIG. 5 offers a top view of a desirable shape of a planar slot antenna.

FIG. 6 represents a perspective view of an antenna section having a rectangular ceiling plate.

FIG. 7 illustrates a perspective view of the antenna section in a state where the rectangular ceiling plate is divided into two parts by a separation plate.

FIG. 8 is a bottom view showing a part of an antenna unit which explains an exemplary arrangement of a plurality of antenna modules for generating circular polarized waves.

FIG. 9 sets forth a cross sectional view of a feed power excitation plate as another example of a feed power conversion unit for supplying power from a main amplifier to a tuner.

FIG. 10 depicts a backside of a printed circuit board of the feed power excitation plate shown in FIG. 9.

FIG. 11 illustrates a backside of a dielectric member of the feed power excitation plate shown in FIG. 9.

FIG. 12 provides a bottom view of a slot antenna of the feed power excitation plate shown in FIG. 9.

FIG. 13 presents a cross sectional view of another feed power excitation plate as another example of the feed power conversion unit for supplying power from the main amplifier to the tuner.

FIG. 14 represents a top view of the feed power excitation plate shown in FIG. 13.

FIG. 15 illustrates a backside of a printed circuit board of the feed power excitation plate shown in FIG. 13.

FIG. 16 explains configurations of an antenna section and a tuner section used in a simulation.

FIG. 17 shows a simulation result.

FIG. 18A illustrates the simulation result.

FIG. 18B depicts the simulation result.

FIG. 19A describes the simulation result.

FIG. 19B presents the simulation result.

FIG. 20 represents a top view of another desirable shape of the planar slot antenna.

### DETAILED DESCRIPTION OF THE EMBODIMENTS

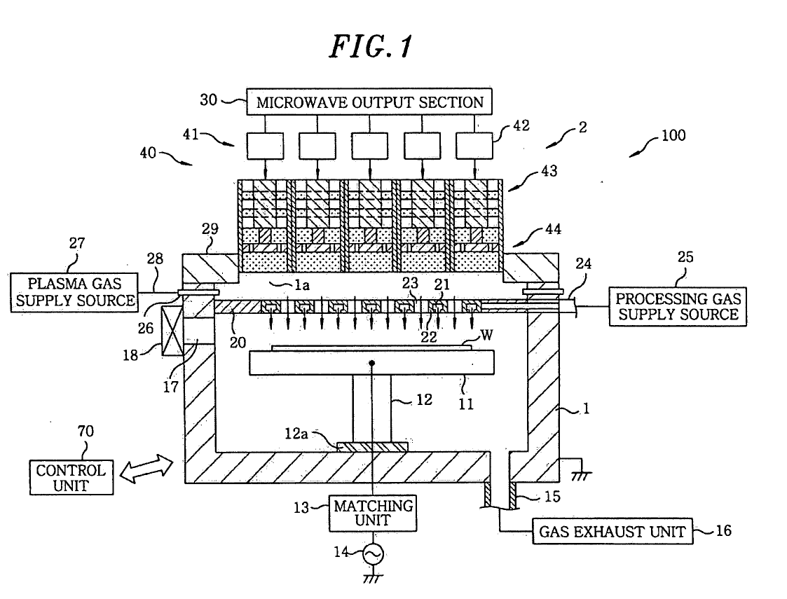

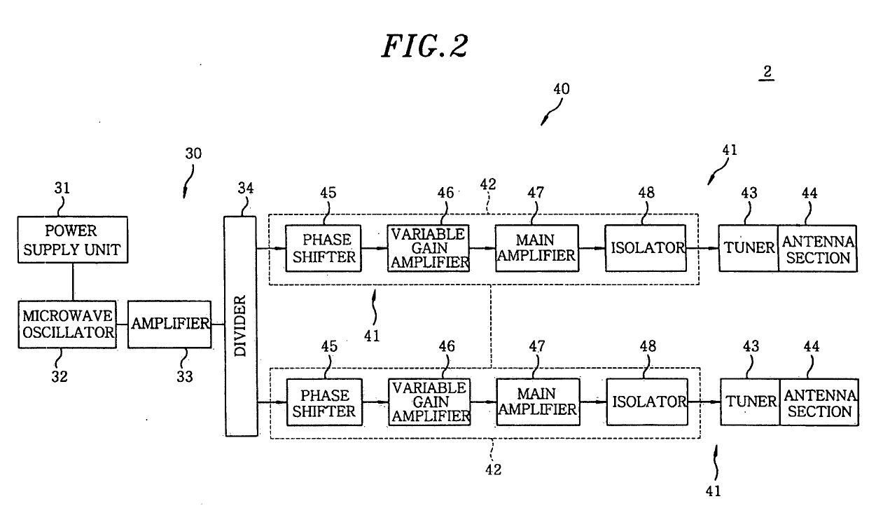

Embodiments of the present invention will be described with reference to the accompanying drawings. FIG. 1 is a cross sectional view showing a schematic configuration of a plasma processing apparatus having a microwave plasma source in accordance with an embodiment of the present invention; and FIG. 2 illustrates a configuration of the microwave plasma source in accordance with the embodiment of the present invention.

A plasma processing apparatus 100 is configured as a plasma etching apparatus for performing plasma processing, e.g., etching, on a wafer, and includes a substantially cylindrical airtight chamber 1 that is grounded and made of a metal material such as aluminum, stainless steel or the like and a microwave plasma source 2 for forming a microwave plasma in the chamber 1. An opening 1a is formed at an upper portion of the chamber 1, and the microwave plasma source 2 is installed toward the interior of the chamber 1 at the opening 1a.

A susceptor 11 for horizontally supporting a wafer W as a target object is installed in the chamber 1 while being supported by a cylindrical supporting member 12 installed upwardly at a center of a bottom portion of the chamber 1 via an insulating member 12a. The susceptor 11 and the supporting member 12 are made of, e.g., aluminum having an alumite treated (anodically oxidized) surface or the like.

Although it is not illustrated, the susceptor 11 is provided with an electrostatic chuck for electrostatically attracting the wafer W, a temperature control mechanism, a gas channel for supplying a heat transfer gas to a backside of the wafer W, an elevating pin for moving up and down to transfer the wafer W and the like. Further, the susceptor 11 is electrically connected to a high frequency bias power supply 14 via a matching unit 13. By supplying a high frequency power from the high frequency bias power supply 14 to the susceptor 11, ions are attracted to the wafer W.

A gas exhaust line 15 is connected to a bottom portion of the chamber 1, and also is connected to a gas exhaust unit 16 having a vacuum pump. By operating the gas exhaust unit 16, the interior of the chamber 1 is exhausted and depressurized to a predetermined vacuum level at a high speed. Moreover, installed on a sidewall of the chamber 1 are a loading/unloading port 17 for loading and unloading the wafer W and a gate valve 18 for opening and closing the loading/unloading port 17.

A shower plate 20 for discharging a processing gas for plasma etching toward the wafer W is horizontally installed above the susceptor 11 in the chamber 1. The shower plate 20 has grid-shaped gas channels 21 and a plurality of gas discharge openings 22 formed in the gas channel 21. A space 23 is formed between the grid-shaped gas channels 21. The gas channel 21 of the shower plate 20 is connected to a line 24 extending to the outside of the chamber 1, and the line 24 is connected to a processing gas supply source 25.

In addition, a ring-shaped plasma gas introducing member 26 is provided along a chamber wall above the shower plate 20 of the chamber 1, and a plurality of gas discharge openings is formed on an inner periphery of the plasma gas introducing member 26. The plasma gas introducing member 26 is connected to a plasma gas supply source 27 for supplying a plasma gas via a line 28. As for a plasma gas, it is proper to use Ar gas.

The plasma gas introduced through the plasma gas introducing member 26 into the chamber 1 is turned into a plasma by microwaves introduced from the microwave plasma source 2 into the chamber 1. The Ar plasma thus generated passes through the space 23 of the shower plate 20, so that the processing gas discharged from the gas discharge openings 22 of the shower plate 20 is excited, and a plasma of the processing gas is formed.

The microwave plasma source 2 is supported by a supporting ring 29 provided at an upper portion of the chamber 1, and the gap therebetween is airtightly sealed. As illustrated in FIG. 2, the microwave plasma source 2 has a microwave outputting section 30 for dividing microwaves and outputting the microwaves to a plurality of channels, and an antenna unit 40 for guiding the microwaves output from the microwave outputting section 30 into the chamber 1 and radiating the guided microwaves into the chamber 1.

The microwave outputting section 30 has a power supply unit 31, a microwave oscillator 32, an amplifier 33 for amplifying the oscillated microwave, and a divider 34 for dividing the amplified microwave into a plurality of microwaves.

The microwave oscillator 32 performs, such as, PLL (Phase Locked Loop) oscillation to generate microwaves of a predetermined frequency (e.g., 2.45 GHz). The divider 34 divides the microwave amplified by the amplifier 33 while matching impedance between an input side and an output side so that the loss of the microwaves can be minimized. In addition, as for the frequency of the microwave, 8.35 GHz, 5.8 GHz, 1.98 GHz or the like may be used instead of 2.45 GHz.

The antenna unit 40 has a plurality of antenna modules 41 for guiding the microwaves divided by the divider 34. Each antenna module 41 is provided with an amplifier section 42 for mainly amplifying the divided microwaves, a tuner 43 for adjusting impedance, and an antenna section 44 for radiating the amplified microwaves into the chamber 1. By radiating the microwaves from the antenna sections 44 of the antenna modules 41 into the chamber 1, the microwaves are combined in the space in the chamber.

The amplifier section 42 has a phase shifter 45, a variable gain amplifier 46, a main amplifier 47 forming a solid state amplifier, and an isolator 48.

The phase shifter 45 is configured to shift phases of the microwaves by a slug tuner, and the radiation characteristics can be modulated by adjusting the phase shifter 45. For example, the plasma distribution can be changed by controlling directivity by adjusting the phase in each of the antenna modules, and the circular polarized waves can be obtained by shifting the phase by 90° between adjacent antenna modules. When there is no need to modulate the radiation characteristics, the phase shifter 45 need not be provided.

The variable gain amplifier 46 is an amplifier for adjusting variation in the antenna modules or plasma intensity by adjusting a power level of microwaves inputted to the main amplifier 47. By changing the variable gain amplifier 46 for each of the antenna modules, the generated plasma distribution can be variably controlled.

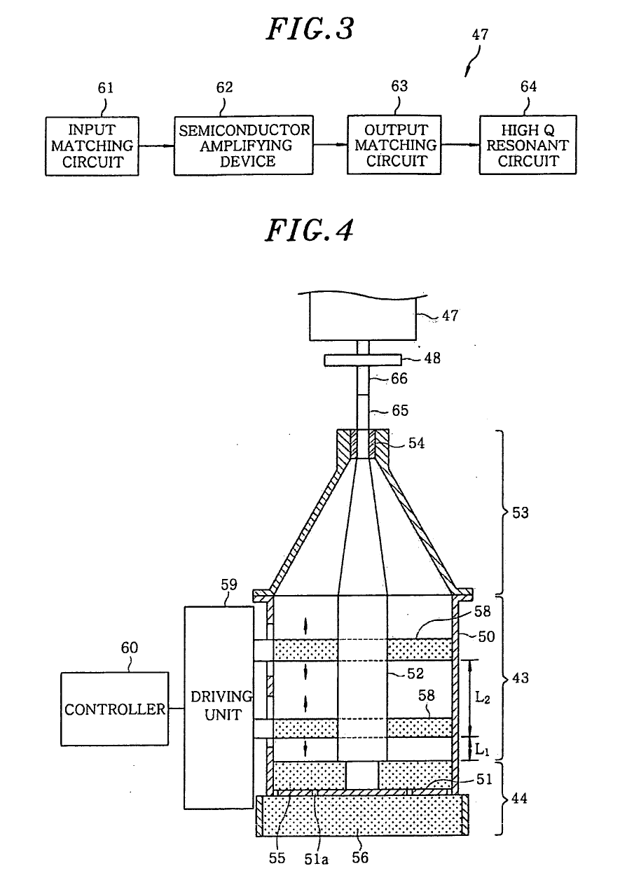

As illustrated in FIG. 3, the main amplifier 47 forming the solid state amplifier has an input matching circuit 61, a semiconductor amplifying device 62, an output matching circuit 63 and a high Q resonant circuit 64. As for the semiconductor amplifying device, it is possible to use GaAs HEMT, GaN HEMT, LD-MOS or the like capable of performing a class E operation. Especially, when GaN HEMT is used as the semiconductor amplifying device 62, the variable gain amplifier has a uniform value, and the power is controlled by varying the power voltage of the amplifier for performing a class E operation.

The isolator 48 separates microwaves reflected to the main amplifier 47 from the antenna section 44, and has a circulator and a dummy load (coaxial terminator). The circulator leads the microwave reflected by the antenna section 44 to the dummy load, and the dummy load coverts the reflected microwave led by the circulator into heat.

In the present embodiment, there is provided a plurality of antenna modules 41, and the microwaves radiated from the antenna sections 44 of the antenna modules are combined in the space. Therefore, the isolator 48 is preferably small-sized, and can be provided adjacent to the main amplifier 47.

The tuner 43 and the antenna section 44 are formed as a unit, as shown in FIG. 4, and have a common housing 50. Moreover, the housing 50 has the antenna section 44 at a lower portion thereof and the tuner 43 at an upper portion thereof. The housing 50, which is cylindrical and made of metal, forms an outer conductor of the coaxial tube.

The antenna section 44 has a planar slot antenna 51 provided with slots 51a, and a metal rod 52 as an inner conductor of the coaxial tube extends upward vertically from the planar slot antenna 51.

A feed power conversion unit 53 is installed at an upper end of the housing 50, and a coaxial connector (N-type connector) 65 is installed at an upper end of the feed power conversion unit 53. Further, the main amplifier 47 is connected to the coaxial connector 65 via a coaxial cable 66. The isolator 48 is provided in the middle of the coaxial cable 66. The main amplifier 47 is a power amplifier dealing with high power and thus performs a high-efficiency operation of a class E or the like. However, the heat therefrom ranges from several tens to several hundreds of kW, so that the main amplifier 47 is installed in series to the antenna section 44 in view of heat radiation. The feed power conversion unit 53 has a microwave transmission path formed to be gradually widened from the coaxial connector 65 to the housing 50.

Although the top surface of the housing 50 is grounded and thus is made of metal, the microwave transmission type can be devised such that the main amplifier 47 may be directly mounted on a top surface of the housing 50. Accordingly, an antenna module may be made compact in size, and also, the antenna module having reliable heat dissipation may be constructed.

Moreover, the isolator 48 is arranged to be located close to the main amplifier 47. Besides, an insulation member 54 is installed at a portion where the metal rod 52 contacts with the upper portion of the feed power conversion unit 53.

The antenna section 44 has a wave retardation member 55 provided on a top surface of the planar slot antenna 51. The wave retardation member 55 has a dielectric constant larger than that of vacuum, and is made of polyimide-based resin or fluorine-based resin, e.g., quartz, ceramic, poly tetrafluoroethylene or the like. Since the wavelength of the microwave is lengthened in the vacuum, the wave retardation member 55 has a function of shortening the wavelength of the microwave, to thereby control the plasma. The wave retardation member 55 can adjust the phases of the microwaves depending on its thickness, and its thickness is adjusted so that the planar slot antenna 51 becomes an antinode of the standing wave. Accordingly, the radiation energy of the planar slot antenna can be maximized while minimizing the reflection.

Further, a dielectric member for vacuum sealing, e.g., a ceiling plate 56 made of quartz, ceramic or the like, is provided on a bottom surface of the planar slot antenna 51. Further, the microwaves amplified by the main amplifier 47 pass through the gap between the main wall of the housing 50 and the metal rod 52 and are radiated into the chamber 1 after being transmitted through the ceiling plate 56 via the slots 51a of the planar slot antenna 51.

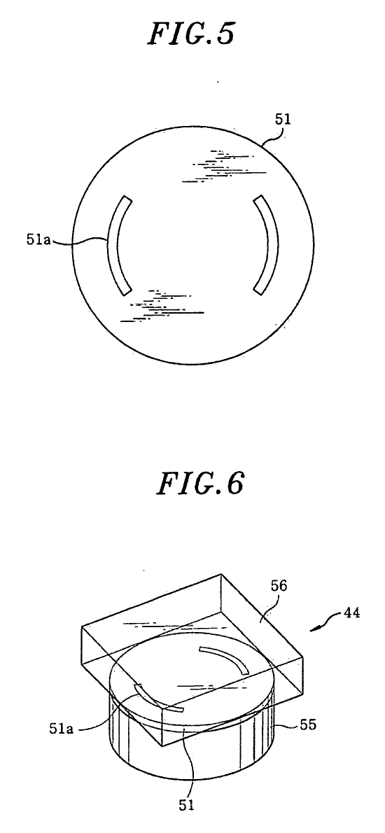

At this time, as shown in FIG. 5, the slots 51a are preferably formed in an arc-shape, and the number thereof is preferably two as illustrated or four. Moreover, the ceiling plate 56 is preferably formed in a rectangular shape (cuboid shape), as can be seen from FIG. 6. Accordingly, the microwave can be effectively transmitted in a TE mode. In addition, as depicted in FIG. 7, it is preferable to divide the rectangular ceiling plate into two parts by a separation plate 57. Accordingly, the pseudo TE wave can pass through the ceiling plate 56 and, hence, the tuning range can be further increased.

The tuner 43 has two slugs 58 positioned above the antenna section 44 of the housing 50, and forms a slug tuner. The slugs 58 are formed as dielectric plate-shaped members, and are disposed in a round ring shape between the metal rod 52 and the outer wall of the housing 50. Further, the impedance is adjusted by vertically moving the slugs 58 by the driving unit 59 based on the instruction from the controller 60. The controller 60 adjusts the impedance of termination to be, e.g., about 50Ω. When only one of the two slugs moves, a path passing through the origin of the smith chart is drawn. On the other hand, when both of them move simultaneously, only the phase rotates.

In the present embodiment, the main amplifier 47, the tuner 43, and the planar slot antenna 51 are arranged to be located close to one another. Further, the tuner 43 and the planar slot antenna 51 form a lumped constant circuit within one wavelength, and also serve as a resonator.

Each unit of the plasma processing apparatus 100 is controlled by a control unit 70 having a micro processor. The control unit 70 has a storage unit which stores process recipes, an input unit, a display and the like, and controls the plasma processing apparatus based on a selected recipe.

Hereinafter, an operation of the plasma processing apparatus configured as described above will be explained.

First of all, the wafer W is loaded into the chamber 1, and is mounted on the susceptor 11. Next, a plasma gas, e.g., Ar gas, is introduced from the plasma gas supply source 27 into the chamber 1 via the line 28 and the plasma gas introducing member 26. At the same time, a microwave is introduced from the microwave plasma source 2 into the chamber 1, thereby forming a plasma.

Thereafter, a processing gas, e.g., an etching gas such as Cl₂ gas or the like, is discharged from the processing gas supply source 25 into the chamber 1 via the line 24 and the shower plate 20. The discharged processing gas is excited by the plasma that has passed through the space 23 of the shower plate 20 to thereby be turned into a plasma. The plasma of the processing gas thus generated is used to perform plasma processing, e.g., an etching process, on the wafer W.

In this case, in the microwave plasma source 2, the microwave oscillated by the microwave oscillator 32 of the microwave outputting section 30 is amplified by the amplifier 33, and is divided into a plurality of microwaves by the divider 34. The divided microwaves are guided to a plurality of antenna modules 41 of the antenna unit 40. In the antenna modules 41, the plurality of divided microwaves are amplified by the main amplifiers 47 forming solid state amplifiers, and are radiated by the planar slot antennas 51, and then microwaves from the antenna modules 41 are combined in a space. Therefore, no large-sized isolator or combiner is required. Further, the antenna section 44 and the tuner 43 are installed as a unit in the same housing, enabling extremely compact installation. Accordingly, the microwave plasma source 2 can be greatly scaled down compared to a conventional one. Further, the main amplifier 47, the tuner 43 and the planar slot antenna 51 are integrally arranged to be located close to one another. Especially, the tuner 43 and the planar slot antenna 51 form a lumped constant circuit, and serve as a resonator. In the planar slot antenna installation portion where the impedance mismatching exists, the tuning can be performed with high accuracy by the tuner 43, and the effects of reflection can be reliably solved.

In addition, tuner 43 is adjacent to planer slot antenna 51 as described above, which forms lumped constant circuit and functions as resonator. The configuration makes impedance mismatching up to planer slot antenna 51 eliminated accurately. This means mismatching portion becomes plasma exclusively, and thus high accurate plasma control is realized by tuner 43. Accordingly, the plasma control can be performed with high accuracy by the tuner 43. Moreover, the ceiling plate 56 attached to the planar slot antenna 51 is formed in a rectangular shape, so that the microwaves can be efficiently radiated as TE waves. Also, the rectangular ceiling plate 56 is divided into two parts by the separation plate 57, so that the pseudo TE wave can pass through the ceiling plate 56. As a consequence, the tuning range can be further increased, and the controllability of the plasma can be improved.

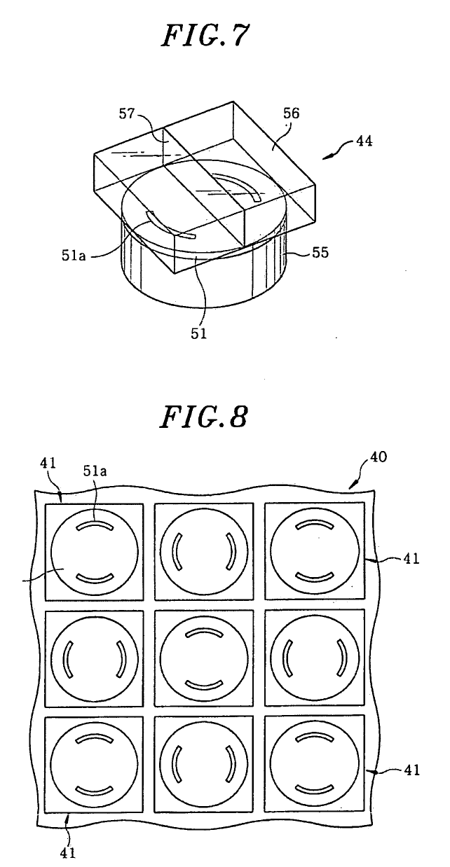

Moreover, by shifting the phase of each antenna module with the use of the phase shifter, the directivity of the microwave can be controlled and, also, the plasma distribution can be easily adjusted. Further, as shown in FIG. 8, a plurality of antenna modules 41 is arranged so that slots 51a of neighboring antenna modules disposed to make 90° therebetween, and the phase shifter 45 adjusts phase difference between neighboring antenna modules to be 90°. Accordingly, the circular polarized waves can be obtained. FIG. 8 shows a part of the antenna unit 40.

The following is a description of another example of the transmission of the microwave power from the main amplifier 47 to the tuner 43.

In the above embodiment, the microwave power is transmitted (fed) from the main amplifier 47 to the tuner 43 by a coaxial feed power conversion unit 53 via the coaxial connector 65. In that case, the transmission path of the feed power conversion unit 53 needs to be gradually widened, and therefore, the apparatus cannot be scaled down. Further, in the above embodiment, a single amplifier is connected to the tuner 43 and, thus, sufficient output may not be obtained.

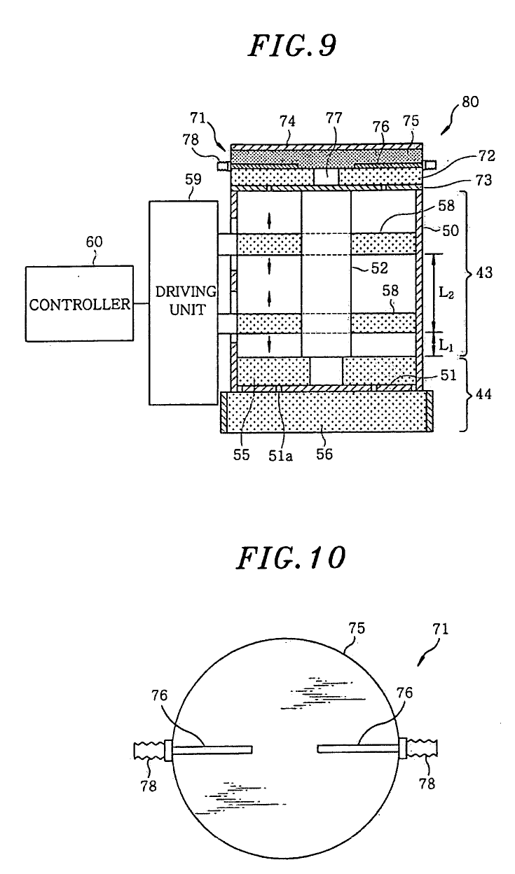

In order to mend the above-described drawback, a feed power excitation plate 80 for performing a non-contact power supply via the dielectric member and the antenna can be used as the feed power conversion unit, as can be seen from FIG. 9. The feed power excitation plate 80 radiates the microwave power transmitted from the main amplifier 47 to the tuner 43, and includes a printed circuit board (PCB) 71 in which microstrip lines 76 are formed on a dielectric board 75, a dielectric member 72 dielectrically coupled to the bottom of the PCB 71, a slot antenna 73 provided on a bottom surface of the dielectric member 72, a reflection plate 74 provided on the top surface of the PCB 71. In FIG. 9, like reference numerals will be used for like parts identical to those used in FIG. 4, and redundant description thereof will be omitted.

As illustrated in FIG. 10, in the PCB 71, the microstrip lines 76 made of a conductor such as Cu or the like are formed on the backside of the dielectric board 75, and connectors 78 are attached to portions corresponding to the microstrip lines 76 on the peripheral surface of the dielectric board 75. The microstrip lines 76 are formed as open stubs, and position relationship between the microstrip lines 76 and the slot antenna thereof is designed so as to have maximum current density at the center of the slot. Since two connectors 78 and two microstrip lines 76 are provided, two amplifiers can be connected thereto. When the microwave powers are supplied from the two connectors 78, the microwave powers are combined (spatially combined) in a resonant portion and then combined microwave is radiated to the tuner. However, the number of the connector 78 and the microstrip line 76 may be one, three, or more than three. Even when the number thereof is equal to or more than three as well as when the number thereof is two, the microwaves are combined in a space.

The dielectric member 72 is made of, e.g., quartz, and serves as a resonator together with the slot antenna 73. As shown in FIG. 11, a central conductor 77 penetrates therethrough to reach the slot antenna 73.

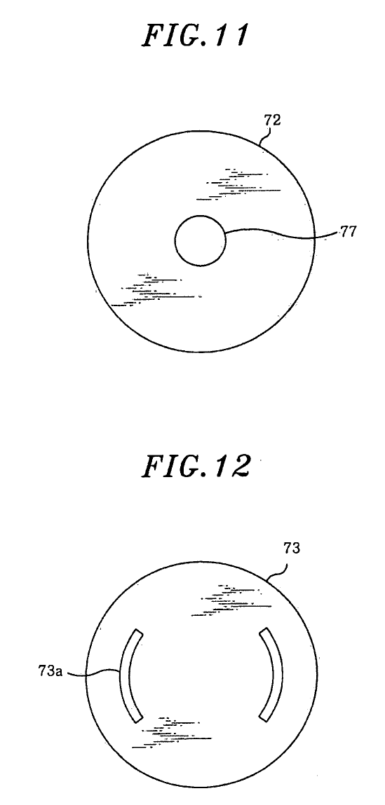

The slot antenna 73 is made of, e.g., Cu, and is formed on the backside of the dielectric member 72 by, e.g., plating, as depicted in FIG. 12. As illustrated, it is provided with, e.g., two arc-shaped slots 73a having a length of about λg/2. However, the slots may have another shape, and the number of the slots may be, e.g., four instead of two. In addition, it is also possible to supply power by a monopole antenna having a wavelength of λg/4 while omitting the slot antenna 73.

The reflection plate 74 is made of, e.g., Cu, and is formed on a top surface of the PCB 71 by, e.g., plating, so that the microwave power is reflected and thus can be prevented from leaking due to radiation.

In the feed power excitation plate 80 configured as described above, the microwave supplied from the main amplifier 47 to the microstrip lines 76 of the PCB 71 via the connectors 78 reaches the slot antenna 73 via the dielectric member 72, and then is radiated from the slots 73a to the tuner 43.

The power supply type used in this case is a non-contact power supply via the dielectric member and the antenna, which is different from a conventional one using a coaxial cable. Since the dielectric member is used as a resonator, the feed power excitation plate 80 as a feed power conversion unit can be scaled down. Further, by providing two or more connectors 78 and microstrip lines 76, the microwave powers can be supplied from a plurality of main amplifiers and the microwave powers are combined in a resonant portion, and then combined microwave is radiated to the tuner 43. In this case, the powers combining is done through a spatial combining, and the combined capacitance can be increased compared to the case where it is combined on a substrate for combination and, also, the feed power conversion unit can be made compact in size. Furthermore, the powers can be combined only by providing a plurality of the connectors 78 and the microstrip lines 76, so that an extremely simple structure can be obtained.

In the micro plasma source shown in FIG. 9, the impedance of the circuit to the tuner is, e.g., 50Ω. Further, the electrical length between the tuner and the antenna is within ½ of wavelength, and since matching is obtained within ½ of wavelength, the tuner and the antenna are regarded as a lumped constant circuit. Also, generation of standing wave is minimized.

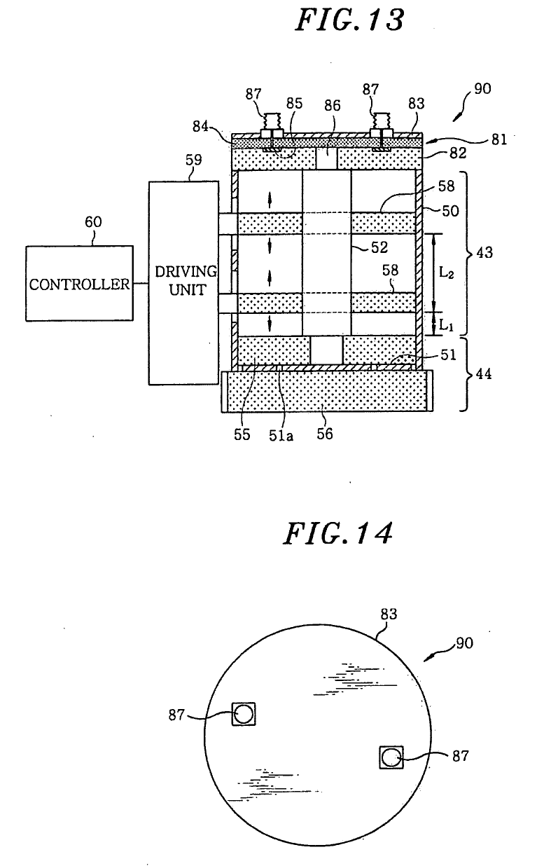

As for another method for transmitting the microwave power from the main amplifier 47 to the tuner 43, there may be used one using a feed power excitation plate using patch antennas 85 shown in FIG. 13. As in the feed power excitation plate 80, a feed power excitation plate 90 shown in FIG. 13 performs a non-contact power supply via the dielectric member and the antenna, and radiates the microwave transmitted from the main amplifier 47 to the tuner 43. The feed power excitation plate 90 includes a printed circuit board (PCB) 81 in which the patch antenna 85 is formed on the dielectric board 84, a dielectric member 82 dielectrically coupled to the bottom of the PCB 81, and a reflection plate 83 provided on the top surface of the PCB 81. Further, in FIG. 13, like reference numerals will be used for like parts identical to those used in FIG. 4, and redundant description thereof will be omitted.

The two connectors 87 for power supply can be attached to a top surface of the PCB 81, and the top surface of the PCB 81 is covered by the reflection plate 83 except the connectors 87, as shown in FIG. 14. As can be seen from FIG. 15, arc-shaped patch antennas 85 are provided at portions corresponding to the two connectors 87 on the backside of the PCB 81 while projecting toward the dielectric board 84. Thus, the power is supplied to the patch antenna 85 via the connectors 87. Power feeding points 85a to the patch antennas 85 are deviated from the central position. Each of the two connectors 87 can be connected to the main amplifier, so that the microwave power can be supplied from the main amplifier to each of the patch antennas 85 via a corresponding connector 87. Further, the number of the connectors 87 and the patch antennas 85 may be one, three, or more than three.

The dielectric member 82 is made of, e.g., quartz, and has a function of transmitting the power radiated from the patch antennas 85 to the tuner 43 therethrough. At this time, the wavelength of the microwave is reduced to λg=λ/(εr)^{1/2} by dielectric constant εr of the dielectric member 82. A central conductor 86 penetrates therethrough to reach the metal rod 52.

The reflection plate 83 is made of, e.g., Cu, and is formed on the top surface of the PCB 81 by, e.g., plating. Accordingly, the microwave power is reflected and thus can be prevented from leaking due to radiation.

In the feed power excitation plate 90 configured as described above, the microwave power from the main amplifier 47 is supplied to the patch antennas 85 of the PCB 81 via the connectors 87 and resonates in the patch antennas 85 to be radiated to the tuner 43 through the dielectric member 82.

The power supply type used in this case is a non-contact power supply via the dielectric member and the antenna, which is different from a conventional one using a coaxial cable. Since the patch antennas 85 and the dielectric member are used as a resonator, the feed power excitation plate 90 as a feed power conversion unit can be scaled down. Further, in the dielectric member 82, the wavelength of the microwave is reduced to λg=λ/(εr)^{1/2}, so that the patch antennas 85 can be scaled down. Furthermore, by providing two or more connectors 87 and patch antennas 85, the power can be supplied from a plurality of main amplifiers, and the microwave powers are combined in a resonant portion, and then are radiated to the tuner 43. In this case, the combination of the powers is achieved through a spatial combining and the combined capacitance can be increased compared to the case where it is combined on a substrate for combination and, also, the feed power conversion unit can be made compact in size. Furthermore, the powers can be combined only by providing a plurality of the connectors 87 and the patch antennas 85, so that an extremely simple structure can be obtained.

Hereinafter, a result of simulation will be explained.

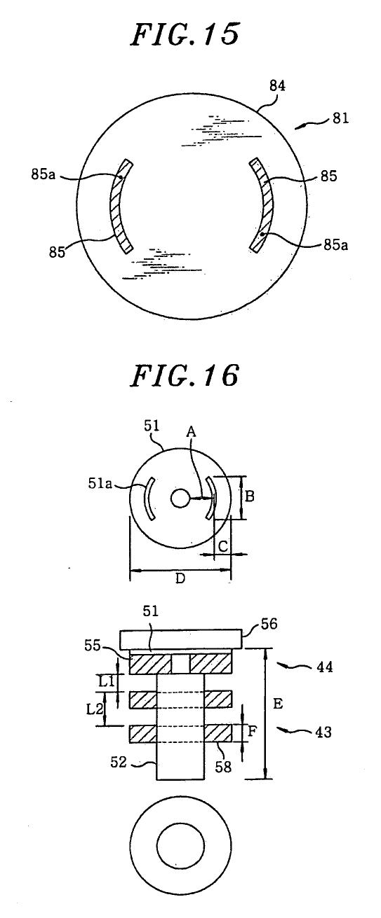

Here, as shown in FIG. 16, two arc-shaped slots 51a were provided at the planar slot antenna 51, and A to F in the drawing were optimized by varying distances L1 and L2 by the two slugs 58 of the tuner 43. The simulation was performed when the rectangular ceiling plate was employed. A notation A indicated a distance from a power feeding point to the slot 51a; a notation B indicated an angle of the slot 51a; a notation C indicated a distance from the slot 51a to the end of the antenna 51; a notation D indicated an outer diameter of the antenna 51; a notation E indicated a distance from the antenna 51 to the end portion of the internal conductor; and a notation F indicated a thickness of the slugs 58. For example, A to F were set to about 15 mm, 78°, 20 mm, 90 mm, 172 mm and 15 mm, respectively.

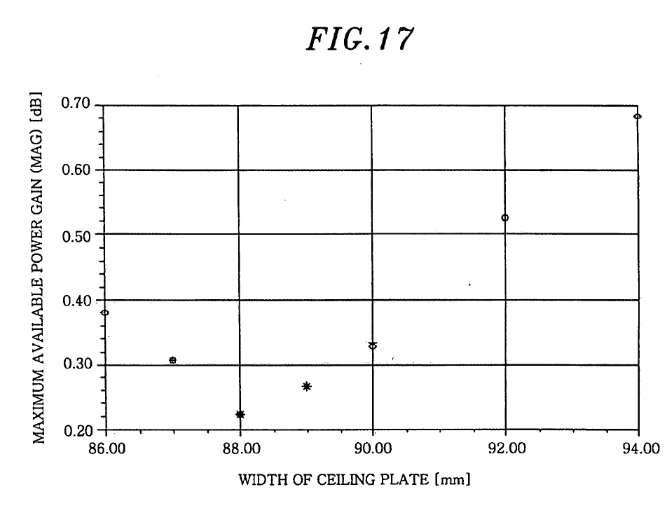

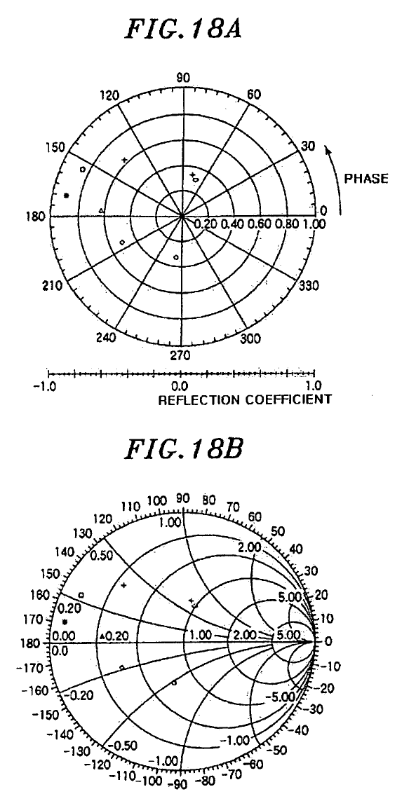

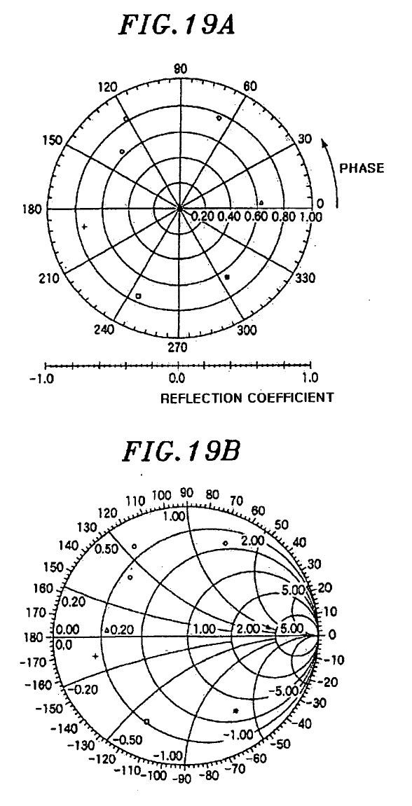

The result thereof is shown in FIG. 17. In FIG. 17, a horizontal axis indicates a width of the ceiling plate 56, and a vertical axis represents a maximum available power gain (MAG) of S₁₁ (reflection coefficient). FIG. 17 shows that the maximum available power gain of S₁₁ can be reduced up to about 0.2 dB. Thus, it has been found that the electromagnetic waves are effectively radiated, and stably propagated in a TE 10 mode regardless of the size of the ceiling plate. However, when the ceiling plate is of a rectangular shape, the tuning range is not sufficient. For that reason, the simulation was performed with the separation plate provided in the middle of the rectangular ceiling plate 56 as illustrated in FIG. 7. The results of a polar chart and a smith chart in case where only one slug 58 is moved are shown in FIGS. 18A and 18B. The results of a polar chart and a smith chart in case where both slugs 58 are moved are shown in FIGS. 19A and 19B. From the results, it has been found that SWWR can be tuned up to 20 levels.

The present invention is not limited to the above embodiment, and can be variously modified within the scope of the present invention. For example, the circuit configurations of the microwave outputting section 30, the antenna unit 40, and the main amplifier 47 are not limited to those described in the above embodiments. To be specific, the phase shifter can be omitted when there is no need to control the directivity of the microwave radiated from the planar slot antenna or obtain the circular polarized waves. Moreover, the antenna unit 40 is not necessarily provided with a plurality of antenna modules 41, and a single antenna module is sufficient in a small-sized plasma source such as a remote plasma or the like. Further, in the main amplifier 47, the semiconductor amplifying devices may be plurally provided.

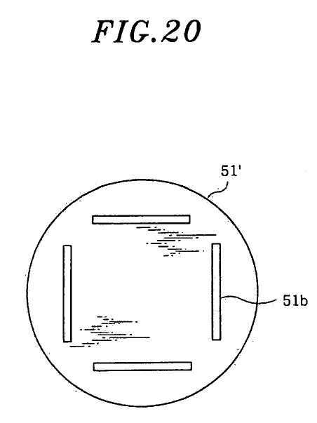

The slot formed at the planar slot antenna 51 is preferably formed in an arc-shape so as to be scaled down by reducing a length thereof, but is not limited thereto. Further, the number of the slots is not limited to those described in the above embodiments. For example, a planar slot antenna 51′ having four slots 51b can be used, as shown in FIG. 20. Although each of the slots 51b has a linear shape in this drawing, it can also be formed in an arc-shape.

Further, although an etching processing apparatus is used as an example of a plasma processing apparatus in the above embodiments, it is not limited thereto. Other plasma processing apparatuses for performing a film forming process, an oxynitride film forming, an ashing process, and the like can be also used. Furthermore, the substrate to be processed is not limited to the semiconductor wafer W but may be FPD (flat-panel display) that is one of the representative substrate for LCD (liquid crystal display), ceramic substrate, and so forth.

What is claimed is:

1. A microwave plasma source for forming a microwave plasma in a chamber, comprising:
a microwave outputting section for outputting a microwave;
an amplifier section having one or more amplifiers for amplifying the microwave;
an antenna section having an antenna for radiating the amplified microwave into the chamber; and
a tuner for adjusting impedance in a microwave transmission path,
wherein the tuner is integrally arranged with the antenna section to be located close to the amplifiers.

2. The microwave plasma source of claim 1, wherein the antenna has a planar shape, and is provided with a plurality of slots.

3. The microwave plasma source of claim 2, wherein the slots have an arc-shape.

4. The microwave plasma source of claim 2, wherein the antenna section has a ceiling plate formed of a dielectric through which the microwave radiated from the antenna is transmitted and a dielectric wave retardation member for shortening a wavelength of the microwave reaching the antenna, the wave retardation member being provided at an opposite side of the ceiling plate with respect to the antenna.

5. The microwave plasma source of claim 4, wherein a phase of a microwave is adjusted by adjusting a thickness of the wave retardation member.

6. The microwave plasma source of claim 4, wherein the ceiling plate has a rectangular shape.

7. The microwave plasma source of claim 6, wherein the ceiling plate is divided into two parts at a center portion thereof.

8. The microwave plasma source of claim 1, wherein the tuner and the antenna form a lumped constant circuit.

9. The microwave plasma source of claim 1, wherein the tuner and the antenna serve as a resonator.

10. The microwave plasma source of claim 1, wherein the tuner is a slug tuner having two dielectric slugs.

11. The microwave plasma source of claim 1, wherein the amplifiers have a semiconductor amplifying device.

12. The microwave plasma source of claim 1, wherein the tuner and the antenna section are integrally arranged in a common housing.

13. The microwave plasma source of claim 12, wherein the amplifiers are connected in series to the antenna section via the tuner by a connector extending upward from the housing.

14. The microwave plasma source of claim 12, wherein the amplifiers are installed directly on a top surface of the housing.

15. The microwave plasma source of claim 1, wherein the amplifier section further has an isolator for separating a reflected microwave from the microwave outputted from the amplifiers to the antenna.

16. The microwave plasma source of claim 1, further comprising a feed power conversion unit for optimally supplying microwave power from the amplifiers to the tuner.

17. The microwave plasma source of claim 16, wherein the feed power conversion unit has a feed power excitation member for performing a non-contact power supply via a dielectric and an antenna.

18. The microwave plasma source of claim 17, wherein the feed power excitation member has one or more open stub microstrip lines formed on a dielectric board; one or more connectors for supplying the microwave power from the amplifiers to the microstrip lines; a dielectric member which serves as a resonator and transmits the microwave power from the microstrip lines; and a slot antenna for radiating the microwave transmitted through the dielectric member to the tuner.

19. The microwave plasma source of claim 18, wherein the numbers of the connectors and the microstrip lines are greater than one, respectively; each of the connectors is connected to an amplifier; and the microwave power from the amplifiers is combined in a space via the microstrip lines.

20. The microwave plasma source of claim 17, wherein the feed power excitation member has one or more patch antennas formed on a dielectric board; one or more connectors for supplying the microwave power from the amplifiers to the patch antennas; and a dielectric member for transmitting the microwave power radiated from the patch antennas therethrough to radiate the transmitted microwave power to the tuner.

21. The microwave plasma source of claim 17, wherein the numbers of the connectors and the patch antennas are greater than one, respectively; each of the connectors is connected to an amplifier; and the microwave power from the amplifiers is combined in a space via the patch antennas.

22. The microwave plasma source of claim 17, wherein the feed power excitation member further has a reflecting plate which is provided on an opposite surface of a microwave power radiating surface to reflect the microwave power.

23. A microwave plasma source for forming a microwave plasma in a chamber, comprising:
a microwave outputting section for outputting plural divided microwaves; and
a plurality of antenna modules for guiding the divided microwaves into a chamber,
wherein each antenna module includes:
an amplifier section having one or more amplifiers for amplifying a microwave;
an antenna section having an antenna for radiating the amplified microwave into the chamber; and
a tuner for adjusting impedance in a microwave transmission path,
wherein the tuner is integrally arranged with the antenna section to be located close to the amplifiers.

24. The microwave plasma source of claim 23, wherein the microwaves guided to the chamber via the respective antenna modules are combined in a space in the chamber.

25. The microwave plasma source of claim 23, wherein the amplifier section has a phase shifter for shifting a phase of a microwave.

26. The microwave plasma source of claim 23, wherein the antenna is formed in a planar shape, and has a plurality of slots.

27. The microwave plasma source of claim 26, wherein the amplifier section has a phase shifter for shifting a phase of a microwave.

28. The microwave plasma source of claim 25, wherein the antenna modules are arranged so that slots of neighboring antenna modules are disposed to make 90° therebetween, and the phase shifter adjusts phase difference between neighboring antenna modules to be 90°.

29. The microwave plasma source of claim 23, wherein the tuner and the antenna section are integrally arranged in a common housing.

30. The microwave plasma source of claim 29, wherein the amplifiers are connected in series to the antenna section via the tuner by a connector extending upward from the housing.

31. The microwave plasma source of claim 29, wherein the amplifiers are directly installed on a top surface of the housing.

32. The microwave plasma source of claim 23, further comprising a feed power conversion unit for optimally supplying microwave power from the amplifiers to the tuner.

33. The microwave plasma source of claim 32, wherein the feed power conversion unit has a feed power excitation member for performing a non-contact power supply via a dielectric and an antenna.

34. The microwave plasma source of claim 33, wherein the feed power excitation member has one or more open stub microstrip lines formed on a dielectric board; one or more connectors for supplying the microwave power from the amplifiers to the microstrip lines; the dielectric member which serves as a resonator and transmits the microwave power from the microstrip lines; and a slot antenna for radiating the microwave transmitted through the dielectric member to the tuner.

35. The microwave plasma source of claim 34, wherein the numbers of the connectors and the microstrip lines are greater than one, respectively; each of the connector is connected to an amplifier; and the microwave power from the amplifiers is combined in a space via the microstrip lines.

36. The microwave plasma source of claim 33, wherein the feed power excitation member has one or more patch antennas formed on a dielectric board, one or more connectors for supplying the microwave power from the amplifier to the patch antennas, and a dielectric member for transmitting the microwave power radiated from the patch antennas therethrough to radiate the transmitted microwave power to the tuner.

37. The microwave plasma source of claim 36, wherein the numbers of the connectors and the patch antennas are greater than one, respectively; each of connectors is connected to an amplifier; and the microwave power from the amplifier is combined in a space via the path antennas.

38. The microwave plasma source of claim 33, wherein the feed power excitation member further has a reflecting plate which is provided on an opposite surface of a microwave power radiating surface to reflect microwave power.

39. A plasma processing apparatus for performing plasma processing on a substrate to be processed in a chamber, the plasma processing apparatus comprising:
the chamber accommodating the substrate to be processed;
a gas supply mechanism for supplying gas into the chamber; and
a microwave plasma source for turning the gas supplied into the chamber into a plasma by a microwave,
wherein the microwave plasma source includes:
a microwave outputting section for outputting a microwave;
an amplifier section having one or more amplifiers for amplifying the microwave;
an antenna section having an antenna for radiating the amplified microwave into the chamber; and
a tuner for adjusting impedance in a microwave transmission path,
wherein the tuner is integrally arranged with the antenna section to be located close to the amplifiers.

40. The plasma processing apparatus of claim 39, wherein the gas supply mechanism has a first gas supply mechanism for introducing a plasma generating gas, and a second gas supply mechanism for introducing a processing gas, wherein the plasma generating gas from the first gas supply mechanism is turned into a plasma by the microwave, and the processing gas from the second gas supplying mechanism is turned into a plasma by the plasma.

41. A plasma processing apparatus for performing plasma processing on a substrate to be processed in a chamber, the plasma processing apparatus comprising:
the chamber accommodating the substrate to be processed;
a gas supply mechanism for supplying gas into the chamber; and
a microwave plasma source for turning the gas supplied into the chamber into a plasma by a microwave,
wherein the microwave plasma source includes:
a microwave outputting section for outputting plural divided microwaves; and
a plurality of antenna modules for guiding the divided microwaves into the chamber,
wherein each antenna module includes:
an amplifier section having one or more amplifiers for amplifying a microwave;
an antenna section having an antenna for radiating the amplified microwave into the chamber; and
a tuner for adjusting impedance in a microwave transmission path,
wherein the tuner is integrally arranged with the antenna section to be located close to the amplifiers.

42. The plasma processing apparatus of claim 41, wherein the gas supply mechanism has a first gas supply mechanism for introducing a plasma generating gas, and a second gas supply mechanism for introducing a processing gas, wherein the plasma generating gas from the first gas supply mechanism is turned into a plasma by the microwave, and the processing gas from the second gas supplying mechanism is turned into a plasma by the plasma.
